(19) United States
(12) Patent Application Publication
(10) Pub. No.: US 2015/0122422 A1
(43) Pub. Date: May 7, 2015

(54) THERMALLY CONDUCTIVE SILICONE SHEET, MANUFACTURING METHOD THEREOF, AND PLASMA PROCESSING APPARATUS USING THE SAME

(71) Applicants: Tokyo Electron Limited, Tokyo (JP); Fuji Polymer Industries Co., Ltd., Nagoya-shi (JP)

(72) Inventors: Yusuke Hayasaka, Kurokawa-gun (JP); Katsuyuki Suzumura, Toyota-shi (JP)

(21) Appl. No.: 14/532,175

(22) Filed: Nov. 4, 2014

(30) Foreign Application Priority Data
Nov. 5, 2013 (JP) 2013-229547

(51) Int. Cl. C09K 5/14; H01J 37/32

(52) U.S. Cl. CPC C09K 5/14; H01J 37/32642; H01J 37/32724; H01J 2237/334; H01J 2237/049
USPC 156/345.53; 252/75

(57) ABSTRACT

A plasma processing apparatus includes a thermally conductive silicone sheet between a mounting table and a focus ring. The thermally conductive silicone sheet has 100 parts by weight to 2000 parts by weight of thermally conductive particles with respect to 100 parts by weight of polyorganosiloxane, and the sheet has a thermal conductivity of 0.2 W/m·K to 5 W/m·K. Further, when the sheet has a shape of 38 mm in length, 38 mm in width, and 3 mm in thickness and is interposed between filter papers each having a diameter of 70 mm and kept under a load of 1 kg at 70° C. for 1 week, a bleed-out amount of a liquid component is 30 mg or less.

### CROSS-REFERENCE TO RELATED APPLICATION

This application claims the benefit of Japanese Patent Application No. 2013-229547 filed on Nov. 5, 2013, the entire disclosures of which are incorporated herein by reference.

### TECHNICAL FIELD

The embodiments described herein pertain generally to a thermally conductive silicone sheet, a manufacturing method thereof, and a plasma processing apparatus using the same, and more particularly, to a thermally conductive silicone sheet having a small bleed-out of a liquid component, a manufacturing method thereof, and a plasma processing apparatus using the thermally conductive silicone sheet to improve temperature controllability of a focus ring used when performing a preset plasma process, such as an etching process, to a target substrate, such as a semiconductor wafer.

### BACKGROUND

Semiconductor device used in electronic devices or the like generates heat while in use, and such heat may cause deterioration in performance of an electronic component. For this reason, a heat radiator is provided in such an electronic component that generates heat. In most cases, the heat radiator is made of metal, so that there is poor adhesion between the electronic component and the heat radiator. For this reason, there has been used a method of increasing adhesivity by inserting a thermally conductive sheet in a gel type or in a soft rubber type.

By way of example, in Patent Document 1, there is suggested a composition including (A) a specific branched organopolysiloxane, (B) a specific organohydrogenpolysiloxane, and (C) an additional reaction catalyst. In Patent Document 2, there is suggested a composition including (A) a straight chain polyorganosiloxane having two or more alkenyl groups bonded with a silicon atom in one molecule and a specific branched organopolysiloxane without having an aliphatic unsaturated bond, (B) a specific organohydrogenpolysiloxane, and (C) a platinum-based catalyst. In Patent Document 3, there is suggested a composition including (A) an organopolysiloxane having alkenyl groups only at both ends of a molecular chain, (B) a thermally conductive filler, (C) an organohydrogenpolysiloxane having hydrogen atoms directly bonded to silicon only at both ends of a molecular chain, and (D) a platinum-based catalyst.

Further, a plasma processing apparatus has been widely used as a semiconductor manufacturing apparatus such as a surface processing apparatus or an etching apparatus. In the plasma processing apparatus, a substrate mounting device that mounts thereon a target substrate such as a wafer is provided within a processing chamber. Further, for example, in Patent Document 4, there is described “a target object mounting device in which a heat insulating vacuum layer is not formed by interposing a heat transfer medium between a mounting table and a focus ring and by providing a pressing unit that presses and fixes the focus ring to the mounting table”.
Patent Document 1: Japanese Patent Laid-open Publication No. 2010-144130
Patent Document 2: Japanese Patent Laid-open Publication No. 2007-154098
Patent Document 3: Japanese Patent Laid-open Publication No. 2004-176016
Patent Document 4: Japanese Patent Laid-open Publication No. 2002-016126

However, the conventional thermally conductive silicone sheet or composition thereof has a problem that there is a large bleed-out amount of a liquid component. Further, if the conventional thermally conductive silicone sheet is used as the heat transfer medium that cools the focus ring of the above-described plasma processing apparatus, temperature controllability of the focus ring may be deteriorated.

### SUMMARY

In view of the foregoing, example embodiments provide a thermally conductive silicone sheet having a small bleed-out amount of a liquid component, a manufacturing method thereof, and a plasma processing apparatus using the same.

In one example embodiment, a thermally conductive silicone sheet for a plasma processing apparatus has 100 parts by weight to 2000 parts by weight of thermally conductive particles with respect to 100 parts by weight of polyorganosiloxane. Further, the sheet has a thermal conductivity of 0.2 W/m·K to 5 W/m·K and a hardness of 5 to 60 (ASKER C), and when the sheet has a shape of 38 mm in length, 38 mm in width, and 3 mm in thickness and is interposed between filter papers each having a diameter of 70 mm and kept under a load of 1 kg at 70° C. for 1 week, a bleed-out amount of a liquid component is 30 mg or less.

In another example embodiment, a manufacturing method of the thermally conductive silicone sheet for the plasma processing apparatus may include forming the sheet by sheet-forming and cross-linking a compound having compositions of: base polymer component (A): A straight chain organopolysiloxane having, on average, two or more alkenyl groups bonded with a silicon atom at both ends of a molecular chain in one molecule and a branched silicone resin without having an aliphatic unsaturated bond but including a R¹SiO_{3/2} unit and/or a SiO_{4/2} unit are included. Here, R¹ represents an organic group which is an unsubstituted monovalent hydrocarbon group or substituted monovalent hydrocarbon group in which at least a part of hydrogen atoms bonded to a carbon atom are substituted with a halogen atom or a cyano group, without having an aliphatic unsaturated bond; cross-linking component (B): A polyorganohydrogen siloxane expressed by R²Si(OSiR³₂H)₃ has 0.3 to 1.5 SiH groups with respect to one alkenyl group of the component (A). Here, R² represents an alkyl group or a phenyl group having 1 to 4 carbon atoms, and R³ represents an alkyl group having 1 to 4 carbon atoms; platinum-based metal catalyst (C): 0.01 ppm to 1000 ppm in a weight unit with respect to the component (A); and thermally conductive particle (D): 100 to 2000 parts by weight with respect to total 100 parts by weight of the component (A) and the component (B).

In yet another example embodiment, a plasma processing apparatus includes a decompressed accommodation chamber in which a target substrate is accommodated; a mounting table which is provided within the accommodation chamber to mount thereon the target substrate and has a cooling device; and an annular focus ring which is mounted on the mounting table to surround a periphery of the target substrate. Further, a thermally conductive silicone sheet is provided between the mounting table and the focus ring, and the thermally conductive silicone sheet has 100 parts by weight to 2000 parts by weight of thermally conductive particles with respect to 100 parts by weight of polyorganosiloxane, and the sheet has a thermal conductivity of 0.2 W/m·K to 5 W/m·K and a hardness of 5 to 60 (ASKER C), and when the sheet has a shape of 38 mm in length, 38 mm in width, and 3 mm in thickness, and is interposed between filter papers each having a diameter of 70 mm and kept under a load of 1 kg at 70° C. for 1 week, a bleed-out amount of a liquid component is 30 mg or less. By providing the thermally conductive silicone sheet between the mounting table and the focus ring, a bleed-out amount of a liquid component is suppressed. Thus, even under the environment in which heat is hardly transferred due to vacuum insulation, heat can be transferred from the mounting table into the focus ring with high efficiency. As a result, it is possible to improve temperature controllability of the focus ring.

In accordance with the example embodiments, it is possible to provide a thermally conductive silicone sheet having a small bleed-out amount of a liquid component such as silicone oil or oligomer, a manufacturing method thereof, and a plasma processing apparatus using the same. In accordance with the example embodiments, it is possible to improve temperature controllability of a focus ring with a thermally conductive silicone sheet provided between contact surfaces of the focus ring and a mounting table.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating a configuration example of a substrate mounting device;

FIG. 2 is a cross-sectional diagram schematically illustrating an example of a plasma processing apparatus in accordance with an example embodiment;

FIG. 3 is a diagram illustrating a configuration of a focus ring in accordance with the example embodiment;

FIG. 4A to FIG. 4C are diagrams illustrating a configuration of a thermally conductive silicone sheet in accordance with the example embodiment; and

FIG. 5 is an explanatory diagram illustrating a method of measuring a bleed-out amount of a liquid component in the thermally conductive silicone sheet in accordance with the example embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Base Polymer Component (A)

A base polymer component includes (A1) a straight chain organopolysiloxane having, on average, two or more alkenyl groups bonded with silicon atoms at both ends of a molecular chain in one molecule; and (A2) a branched silicone resin without having an aliphatic unsaturated bond but including a R¹SiO_{3/2} unit and/or a SiO_{4/2} unit.

Component (A1)

The component (A1) is an organopolysiloxane having two or more alkenyl groups bonded with a silicon atom in one molecule, and is a base compound of a silicone rubber composition of the example embodiment. The organopolysiloxane has two alkenyl groups, such as vinyl groups or allyl groups having 2 to 8, particularly 2 to 6 carbon atoms, boned with silicon atoms in one molecule. Desirably, the organopolysiloxane has a viscosity of 10 mPa·s to 1000000 mPa·s, particularly 100 mPa·s to 100000 mPa·s, at 25° C. in terms of workability, hardenability, and the like.

To be specific, there is used an organopolysiloxane having, on average, two or more alkenyl groups bonded with the silicon atoms at both ends of a molecular chain in one molecule, which can be expressed by the following general formula (chemical formula 1). The organopolysiloxane is a straight chain organopolysiloxane of which side chains are blocked by triorganosiloxy groups. Desirably, a viscosity thereof is 10 mPa·s to 1000000 mPa·s at 25° C. in terms of workability, hardenability, and the like. Further, the straight chain organopolysiloxane may contain a small amount of branched structures (trifunctional siloxane units) in a molecular chain.

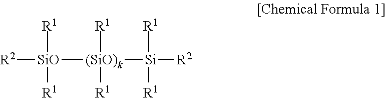

In the above formula, R¹ represents the same or different substituted or unsubstituted monovalent hydrocarbon group without having an aliphatic unsaturated bond, R² represents an alkenyl group, and k represents an integer of 0 or more.

Herein, desirably, the substituted or unsubstituted monovalent hydrocarbon group without having an aliphatic unsaturated bond represented by R¹ may have, for example, 1 to 10, particularly 1 to 6, carbon atoms, and may specifically include: alkyl groups such as a methyl group, an ethyl group, a propyl group, an isopropyl group, a butyl group, an isobutyl group, a tert-butyl group, a pentyl group, a neopentyl group, a hexyl group, a cyclohexyl group, an octyl group, a nonyl group, a decyl group, etc.; aryl groups such as a phenyl group, a tolyl group, a xylyl group, a naphthyl group, etc.; aralkyl groups such as a benzyl group, a phenylethyl group, a phenylpropyl group, etc.; and groups in which the hydrogen atoms of the groups indicated above are partly or wholly substituted with a halogen atom such as fluorine, bromine, chlorine or the like, or a cyano group or the like, e.g., halogen-substituted alkyl groups including a chloromethyl group, a chloropropyl group, a bromoethyl group and a trifluoropropyl group, or a cyanoethyl group. Desirably, the alkenyl group represented by R² may have, for example, 2 to 6, particularly 2 to 3, carbon atoms, and may specifically be: a vinyl group, an allyl group, a propenyl group, a isopropenyl group, a butenyl group, an isobutenyl group, a hexenyl group, a cyclohexenyl group, etc., desirably a vinyl group.

In the general formula (chemical formula 1), typically, k is 0 or a positive integer satisfying 0≦k≦10000, desirably 5≦k≦2000, and more desirably 10≦k≦1200.

Component (A2)

The component (A2) added to the base polymer is a branched silicone resin without having an aliphatic unsaturated bond, and includes a R¹SiO_{3/2} unit and/or a SiO_{4/2} unit. Desirably, it is a polyorganosiloxane which can be expressed by an average unit formula (R¹₃SiO_{1/2})ₐ(R¹₂SiO_{2/2})_{b}(R¹SiO_{3/2})_{c}(SiO_{4/2})_{d}(XO_{1/2})ₑ. In the formula, R¹ represents the same or different substituted or unsubstituted monovalent hydrocarbon group without having an aliphatic unsaturated bond. R¹ may include: alkyl groups such as a methyl group, an ethyl group, a propyl group, an isopropyl group, a butyl group, an isobutyl group, a tert-butyl group, a hexyl group, a cyclohexyl group, an octyl group, etc.; aryl groups such as a phenyl group, a tolyl group, etc.; aralkyl groups such as a benzyl group, a phenylethyl group, etc.; and groups in which at least a part of the hydrogen atoms bonded to a carbon atom of the groups indicated above are substituted with a halogen atom such as fluorine, chlorine, bromine or the like, or a cyano group or the like, e.g., halogen-substituted alkyl groups including a chloromethyl group, a 2-bromoethyl group, a 3-chloropropyl group, a chlorophenyl group, a fluorophenyl group, a cyanoethyl group a cyano-substituted alkyl group, a halogen-substituted aryl group, or the like. Particularly, a methyl group is desirable. X represents a hydrogen atom or an alkyl group. Examples of the alkyl group are the same as described above, and particularly, a methyl group is desirable. Further, a is 0 or an integer, b is 0 or an integer, at least any one of c or d is an integer, e is 0 or an integer, and they satisfy 0≦a/(c+d)<4, 0≦b/(c+d)<2, and 0≦e/(a+b+c+d)<0.4. The component (A2) may be used alone or as a mixture of two or more thereof.

Desirably, the component (A1) and the component (A2) has a weight ratio (A1)/(A2) of 60/40 to 90/10. Within this range, a desirable low bleed-out amount and a highly filling property of a thermally conductive filler can be satisfied, and favorable properties of a hardened product in a gel type or in a soft rubber type can be obtained.

Cross-Linking Component (B)

The component (B) can be expressed by a general formula: R²Si(OSiR³₂H)₃. In the formula, R² represents an alkyl group or a phenyl group having 1 to 4 carbon atoms. R² may include an alkyl group such as a methyl group, an ethyl group, a propyl group, a butyl, etc., and a phenyl group. In particular, a methyl group or a phenyl group is desirable since it is easy to synthesize. R³ represents an alkyl group having 1 to 4 carbon atoms. R³ may include an alkyl group such as a methyl group, an ethyl group, a propyl group, a butyl, etc. In particular, a methyl group is desirable since it is easy to obtain a material and it is also easy to synthesize. As the component (B), it is desirable to solely use a siloxane expressed by the above general formula.

Component (C)

The component (C) is configured to promote hardening of the present composition. As the component (C), there may be used a catalyst well known as a catalyst used in hydrosilylation reaction. Examples of the component (C) may be platinum-based catalysts such as platinum black, platinum chloride, chloroplatinic acid, a reaction product of chloroplatinic acid and monovalent alcohol, a complex of chloroplatinic acid and olefins or vinyl siloxane, platinum bis acetoacetate, and platinum group metal catalysts such as a palladium-based catalyst, a rhodium-based catalyst, etc. An amount of the component (C) to be mixed can be appropriately adjusted depending on a desired hardening rate as long as it satisfies an amount required for hardening. The component (C) is added in a weight unit of 0.01 ppm to 1000 ppm with respect to the component (A).

Component (D)

Thermally conductive particles of the component (D) are added in an amount of 100 parts by weight to 2000 parts by weight with respect to total 100 parts by weight of the component (A) and the component (B). Thus, the thermally conductive sheet may have a thermal conductivity of 0.2 W/m·K to 5 W/m·K and a hardness of 5 to 60 in the Asker Type C. Desirably, the thermally conductive particles may be at least one selected from alumina, zinc oxide, magnesium oxide, aluminum nitride, boron nitride, aluminum hydroxide, and silica. Further, the thermally conductive particles may have various shapes such as a spherical shape, a scale shape, a polyhedral shape, etc. In the case of using alumina, desirably, α-alumina having a purity of 99.5 weight % or more is desirable. Desirably, the thermally conductive particles have a specific surface area of 0.06 m²/g to 10 m²/g. The specific surface area is the BET specific surface area and measured according to JIS R1626. An average particle diameter may be in a range of, desirably, 0.1 μm to 100 μm. In measuring a particle diameter, a 50% particle diameter is measured by a laser diffraction/scattering method. Herein, the measuring apparatus may be, for example, a laser diffraction/scattering type particle size distribution analyzer LA-95052 manufactured by Horiba Ltd.

Desirably, the thermally conductive particles may include at least two inorganic particles different from each other in average particle diameter. This is because in this case, a gap between the thermally conductive inorganic particles having a larger particle diameter is filled with the thermally conductive inorganic particles having a smaller particle diameter. As a result, a closest-filling state can be obtained, and a thermal conductivity can be increased. Desirably, the thermally conductive inorganic particles having a relatively smaller average particle diameter are surface-treated with a silane compound expressed by R(CH₃)ₐSi(OR′)₃₋ₐ (R represents a substituted or unsubstituted organic group having 6 to 20 carbon atoms, R′ represents an alkyl group having 1 to 4 carbon atoms, and a is 0 or 1), or a partial hydrolysate thereof. The silane compound expressed by R(CH₃)ₐSi(OR′)₃₋ₐ (R represents a substituted or unsubstituted organic group having 6 to 20 carbon atoms, R′ represents an alkyl group having 1 to 4 carbon atoms, and a is 0 or 1) (hereinafter, simply referred to as “silane”) may be, for example, hexyltrimethoxysilane, hexyltriethoxysilane, octyltrimethoxysilane, octyltriethoxysilane, decyltrimethoxysilane, decyltriethoxysilane, dodecyltrimethoxysilane, dodecyltriethoxysilane, hexadodecyltrimethoxysilane, hexadodecyltriethoxysilane, octadecyltrimethoxysilane, octadecyltriethoxysilane, and the like. The silane compound may be used alone or as a mixture of two or more thereof. Herein, the term “surface treatment” includes adsorption or the like besides the covalent bond. Desirably, the thermally conductive inorganic particles having a relatively larger average particle diameter may have, for example, an average particle diameter of 2 μm or more, and may be added in an amount of 50 weight % or more with respect to 100 weight % of the total particles.

Other Component (E)

The composition of the present example embodiment may include components other than the above-described components, if necessary. By way of example, an inorganic pigment such as red oxide or alkyltrialkoxysilane for the surface treatment of the filler may be added.

The thermally conductive silicone sheet of the present example embodiment has a thermal conductivity of 0.2 W/m·K to 5 W/m·K, desirably 0.5 W/m·K to 3 W/m·K, and more desirably 1 W/m·K to 2 W/m·K. Further, the thermally conductive silicone sheet of the present example embodiment has a hardness of 5 to 60, more desirably 5 to 40. In the above ranges, heat can be transferred with high efficiency by interposing the thermally conductive silicone sheet between the heat generating element and the heat radiator.

Hereinafter, the bleed-out of a liquid component will be explained. The sheet of the present example embodiment has a shape of 38 mm in length, 38 mm in width, and 3 mm in thickness. When the sheet is interposed between filter papers each having a diameter of 70 mm and kept under a load of 1 kg at 70° C. for 1 week, the bleed-out amount of the liquid component is 30 mg or less. The above-mentioned load and temperature are substantially approximate to the conditions when the sheet is mounted on an electronic component. In the above range, the sheet has a small bleed-out amount, and thus, has a small effect on semiconductor devices and other electronic components. A measurement method will be explained in experimental examples.

(Plasma Processing Apparatus)

Hereinafter, an example of a plasma processing apparatus in accordance with the present example embodiment including the above-described thermally conductive silicone sheet will be explained with reference to the accompanying drawings. Further, the plasma processing apparatus of the present example embodiment is not limited to the configuration to be described below.

The plasma processing apparatus includes a decompressed accommodation chamber (processing chamber) in which a target substrate is accommodated, a mounting table which is provided within the accommodation chamber to mount thereon the target substrate and includes a cooling device; and an annular focus ring which is mounted on the mounting table to surround a periphery of the target substrate. Herein, in the plasma processing apparatus, the above-described thermally conductive silicone sheet is provided between the mounting table and the focus ring.

Further, in the plasma processing apparatus, there is provided a pressing unit configured to press the focus ring against the mounting table. By way of example, the focus ring is formed of a ring-shaped lower member in contact with the mounting table and a ring-shaped upper member mounted on the lower member via the thermally conductive silicone sheet, and the pressing unit is configured to fix the lower member to the mounting table by screw fixing. Further, in the plasma processing apparatus, the lower member is made of a dielectric material or a conductive material.

FIG. 1 is a diagram illustrating a configuration example of a substrate mounting device. The substrate mounting device includes, for example, as depicted in FIG. 1, a mounting table 2 configured to mount thereon a wafer 1 and a focus ring 3 provided at an outer periphery of the mounting table 2.

When a plasma process is performed to the wafer 1, after the wafer 1 is mounted on the mounting table 2, while maintaining the processing chamber at a preset vacuum level, the wafer 1 is fixed, a high frequency voltage is applied to the mounting table 2 to generate plasma within the processing chamber.

Herein, the focus ring 3 is provided to allow the entire surface of the target substrate to be uniformly plasma-processed by suppressing plasma from being discontinuously distributed at the periphery of the target substrate. For this reason, the focus ring 3 is made of a conductive material and a height of an upper surface of the focus ring 3 is set to be substantially the same as a height of a processing surface of the target substrate. Thus, even at the periphery of the target substrate, ions can be vertically incident to the surface of the target substrate, and there is no difference in ion density between the periphery of the target substrate and the center thereof. Thus, however, the target substrate and the focus ring 3 have substantially the same potential and plasma is likely to be introduced to a rear end side of the target substrate depending on a shape of an electric field. As a result, at a rear surface side of the periphery (edge) of the target substrate, deposits (deposition) formed of CF-based polymer or the like may be generated.

Further, since it is very important to control a temperature of the wafer 1 in the plasma process, the wafer 1 is cooled to a desired temperature by the cooling device provided within the mounting table 2. By way of example, a thermal conductivity between the wafer 1 and the mounting table 2 can be increased by allowing a helium gas having a high thermal conductivity to be supplied into a gap between the upper surface of the mounting table 2 and the rear surface of the wafer 1.

Furthermore, within the decompressed accommodation chamber, a heat insulating vacuum layer is formed between the mounting table 2 and the focus ring 3, and, thus, a thermal conductivity between the mounting table 2 and the focus ring 3 is very low. Therefore, since it is difficult to cool the focus ring 3, a temperature of the focus ring 3 may become too high, so that a composition ratio or density of ions and radicals in the plasma at the periphery of the wafer is changed. As a result, for example, an etching rate and a hole profile (a property of clearly digging to a preset depth by the etching) of the periphery of the wafer, and an etching selectivity of an etching mask with respect to an etching target film may be decreased, or an etching aspect ratio may be decreased. As such, etching characteristics at the periphery of the wafer is deteriorated. That is, the focus ring needs to be controlled to a desired temperature by increasing temperature controllability of the focus ring.

Herein, in the plasma processing apparatus in accordance with the present example embodiment, the above-described thermally conductive silicone sheet is provided between the mounting table and the focus ring, as explained in detail below.

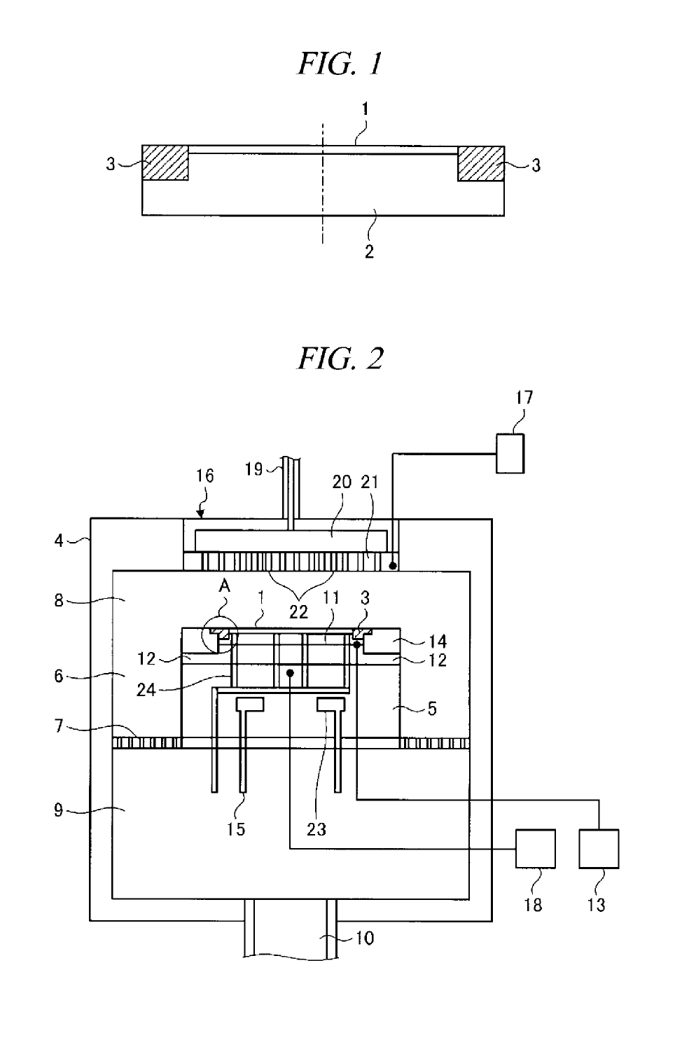

FIG. 2 is a cross-sectional diagram schematically illustrating an example of a plasma processing apparatus in accordance with the present example embodiment. The plasma processing apparatus is configured as a capacitively coupled parallel plate type plasma etching apparatus, and includes, for example, a substantially cylindrical chamber (processing vessel) 4 made of aluminum of which a surface is anodically oxidized. The chamber 4 is frame-grounded.

The plasma processing apparatus includes the chamber that accommodates the semiconductor wafer 1, and within the chamber 4, an electrostatic chuck 12 and a cylindrical susceptor 5 are provided as a mounting table configured to mount thereon the wafer 1. Between an inner wall surface of the chamber 4 and a side surface of the susceptor 5, a side exhaust path 6 configured to exhaust a gas is formed. In the middle of the side exhaust path 6, an exhaust plate 7 formed of a porous plate is provided. The exhaust plate 7 functions as a partition plate that divides the chamber 4 into upper and lower parts. The upper part of the exhaust plate 7 serves as a reaction chamber 8, and the lower part thereof serves as an exhaust chamber 9. In the exhaust chamber 9, an exhaust pipe 10 is opened, and the inside of the chamber 4 is vacuum-exhausted by a non-illustrated vacuum pump.

The mounting table is formed of the susceptor 5 and the electrostatic chuck 12, and the electrostatic chuck 12 including an electrostatic electrode plate 11 therein is provided on the susceptor 5. The electrostatic chuck 12 includes a lower disc-shaped member and an upper disc-shaped member having a smaller diameter, which are stacked in sequence. On an upper surface of the upper disc-shaped member, a dielectric material layer (ceramics or the like) is formed. By applying a DC high voltage to the electrostatic electrode plate 11 connected to a DC power supply 13, a dielectric potential is generated on the surface of the upper disc-shaped member to attract and hold the wafer 1 mounted thereon by the Coulomb force or the Johnsen-Rahbek force.

The electrostatic chuck 12 is fixed to the susceptor 5 by screw fixing, and the focus ring 3 is provided between an insulating member 14 and the wafer 1. The insulating member 14 is configured to suppress excessive diffusion of plasma toward an outer periphery and controls an electric field in order for plasma not to be excessively diffused and not to be discharged from the exhaust plate 7 toward the exhaust side. Further, the surface of the focus ring 3 is made of a conductive material such as silicon, silicon carbide, or the like. The focus ring 3 covers the outer periphery of the wafer 1 and the surface thereof is exposed to a space of the reaction chamber 8, so that plasma within the reaction chamber can be collected on the wafer by the focus ring 3.

Plasma is generated within the reaction chamber by applying a high frequency power from an upper high frequency power supply 17 to a gas inlet shower head 16 provided at an upper part of the reaction chamber 8 and by applying a high frequency power from a lower high frequency power supply 18 to the susceptor 5. A reaction gas is supplied to the gas inlet shower head 16 through a gas inlet line 19. Further, the reaction gas is excited into plasma while flowing through a buffer room 20 and multiple gas holes 22 formed in an upper electrode plate 21, and supplied to the reaction chamber 8.

The temperature of the wafer 1 exposed to the high-temperature plasma is increased, so that it is cooled by conducting the heat to the susceptor 5. For this reason, the susceptor 5 is made of a metal material having a high thermal conductivity, and includes therein a coolant path 23 through which a coolant such as water or ethylene glycol supplied through a coolant supply line 15 is circulated. Further, multiple thermally conductive gas supply holes 24 are formed in a surface of the susceptor 5 to which the wafer 1 is adsorbed, and helium is discharged through these holes to cool the rear surface of the wafer 1.

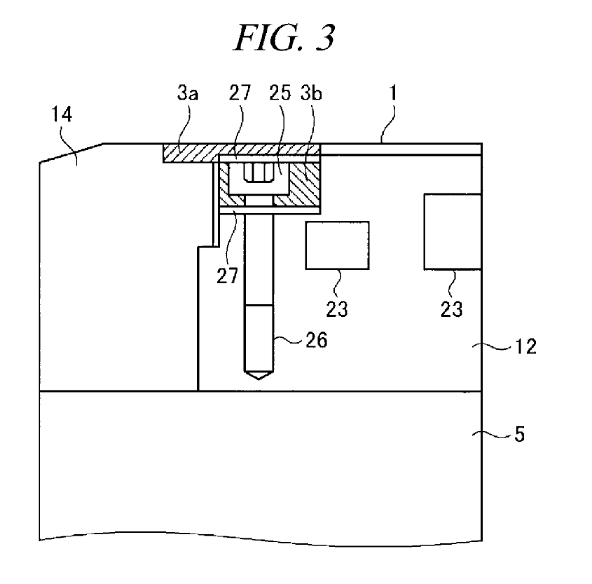

FIG. 3 is a cross-sectional view illustrating a detail configuration of the focus ring 3 in this example embodiment. FIG. 3 is an enlarged view of a portion A in FIG. 2. The wafer 1 is adsorbed to and held on the electrostatic chuck 12. The electrostatic chuck 12 is fixed to the susceptor 5 by screw fixing, and the coolant path 23 is formed within the electrostatic chuck 12.

The focus ring 3 is formed of an upper member 3a and a lower member 3b. A thermally conductive silicone sheet 27 is interposed between the upper member 3a and the lower member 3b and configured to promote heat conductance of the focus ring 3. Further, the lower member 3b is a ring-shaped member made of a dielectric material or a conductive material, and is fixed on the electrostatic chuck 12 via the thermally conductive silicone sheet 27. The upper member 3a is a ring-shaped member made of a conductive material, and is mounted on the lower member 3b via the thermally conductive silicone sheet 27. On the lower member 3b, there is formed a bolt hole (a hole for accommodating a bolt head 25) that penetrates the lower member 3b. In the electrostatic chuck 12, there is formed a screw coupled to a bolt end portion 26.

The thermally conductive silicone sheet 27 is also provided between the lower member 3b and the electrostatic chuck 12. This thermally conductive silicone sheet 27 is interposed between the contact surfaces of the focus ring 3 and the electrostatic chuck 12 used to promote the heat conductance therebetween. Further, the thermally conductive silicone sheet 27 is made of a polymer material having a high flexibility and a high thermal conductivity.

In the present example embodiment, the thermally conductive silicone sheet 27 is provided between the upper member 3a and the lower member 3b, and also provided between the lower member 3b and the electrostatic chuck 12. Further, the lower member 3b and the electrostatic chuck 12 are fixed with a bolt. With this configuration, a thermal conductivity between the focus ring 3 and the electrostatic chuck 12 can be improved, and a temperature of the focus ring 3 can be controlled to a desired level with high efficiency.

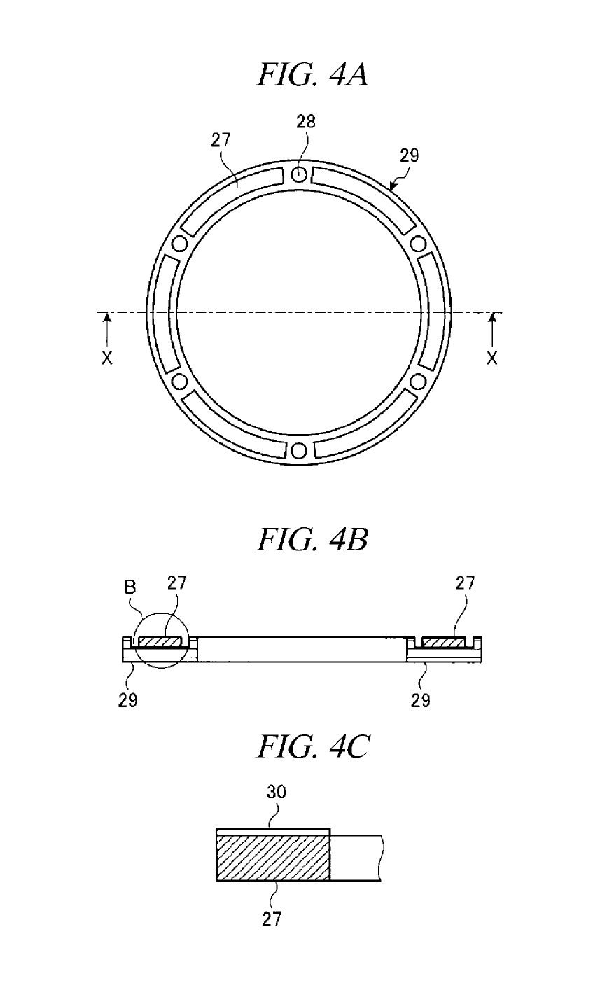

FIG. 4A to FIG. 4C are diagrams illustrating a configuration of the thermally conductive silicone sheet 27 used in the present example embodiment. FIG. 4A is a bottom view when viewed from the electrostatic chuck 12, FIG. 4B is a cross-sectional view taken along a line indicated by arrows X-X in FIG. 4A, and FIG. 4C is an enlarged view of a portion B in FIG. 4B. The thermally conductive silicone sheet 27 is attached to a ring 29 in which bolt holes 28 are formed at a preset interval therebetween, and a non-adhesive layer 30 is formed on a surface (which is an upper surface in this drawing, but becomes a lower surface since the ring is upside down when actually used). In this example embodiment, six bolt holes 28 are formed, but without limitation thereto, twelve bolt holes 28 may be formed.

Further, in the above description, there has been explained the case where the thermally conductive silicone sheet 27 is provided between the upper member 3a and the lower member 3b and between the lower member 3b and the electrostatic chuck 12, but the present example embodiment is not limited thereto. By way of example, the thermally conductive silicone sheet 27 may be provided only at any one portion of a portion between the upper member 3a and the lower member 3b and a portion between the lower member 3b and the electrostatic chuck 12. In this case, desirably, the thermally conductive silicone sheet 27 may be provided only between the upper member 3a and the lower member 3b.

Otherwise, the thermally conductive silicone sheet 27 may be provided at a portion other than the portion between the upper member 3a and the lower member 3b and the portion between the lower member 3b and the electrostatic chuck 12. By way of example, in the plasma processing apparatus, the thermally conductive silicone sheet 27 may be provided between contact surfaces of the upper electrode plate 21 and the shower head 16. Here, if either one or both of the upper electrode plate 21 and the shower head 16 are in contact with a non-illustrated cooling jacket, the thermally conductive silicone sheet 27 may be provided on a contact surface with respect to the cooling jacket. That is, by way of example, if the thermally conductive silicone sheet 27 is provided between the upper member 3a and the lower member 3b, a temperature of the focus ring 3 is increased as compared with the case of using the conventional sheet. As a result, it can be assumed that with respect to a temperature of the outer periphery of the upper electrode plate 21, a temperature of the focus ring 3 is increased as compared with the case of using the conventional sheet. Based on this assumption, it is possible to appropriately control a temperature of the upper electrode plate 21 by providing the thermally conductive silicone sheet 27 instead of the conventional sheet, for example, between the upper electrode plate 21 and the cooling jacket.

(Effect of Plasma Processing Apparatus)

As described above, the plasma processing apparatus in accordance with the present example embodiment includes the decompressed accommodation chamber in which the target substrate is accommodated; the mounting table which is provided within the accommodation chamber to mount thereon the target substrate and includes the cooling device; and the annular focus ring 3 which is mounted on the mounting table to surround the periphery of the target substrate, and the above-described thermally conductive silicone sheet is provided between the mounting table and the focus ring 3. As a result, a temperature of the focus ring 3 can be controlled to be higher, so that it is possible to improve a mask selectivity of an etching mask.

Further, in the plasma processing apparatus in accordance with the present example embodiment, the bleed-out from the thermally conductive silicone sheet is suppressed as compared with the conventional sheet. As a result, it is possible to improve maintainability. If oil leaks from the sheet, adhesion between the sheet and another member is increased. Herein, for example, the focus ring is one of consumables, and thus, is required to be regularly replaced. Since it is difficult to remove the sheet from the focus ring due to the oil leaking from the sheet, maintenance becomes difficult. In this regard, according to the above-described plasma processing apparatus, an oil bleed-out is suppressed as compared with the case of using the conventional sheet. Therefore, maintenance becomes easy. Further, according to the above-described plasma processing apparatus, in the case of using the conventional sheet, when the focus ring and the sheet are firmly fastened with a screw, maintainability may be further deteriorated due to the adhesion increase caused by the oil bleeding in addition thereto. Meanwhile, in the above-described plasma processing apparatus, the adhesion caused by the oil bleeding is suppressed, so that the focus ring and the sheet can be firmly fastened with a screw to be adequately fixed.

### VARIOUS MODIFICATION EXAMPLES

Further, the present disclosure is not limited to the above-described example embodiment, and can be modified and changed in various ways. By way of example, in the above-described example embodiment, the thermally conductive silicone sheet 27 according to a following experimental example 1 is provided between the lower member 3b and the electrostatic chuck 12, but the thermally conductive silicone sheet 27 according to a following experimental example 2 may be provided. Further, in the above-described example embodiment, the focus ring is divided into the two members: the upper member 3a; and the lower member 3b, and the thermally conductive silicone sheet 27 is inserted therebetween. However, even if the focus ring 3 has a single ring-shaped structure in which the upper member 3a and the lower member 3b are not divided, the thermally conductive silicone sheet 27 may be provided between the focus ring and the mounting table. In the above-described example embodiment, the semiconductor wafer is used as the target substrate. However, in the present disclosure, the target substrate is not limited to the semiconductor wafer, and may include other substrates such as a FPD (Flat Panel Display) or the like.

### Experimental Examples

The present disclosure will be explained in detail with reference to the experimental examples, but may not be limited to the experimental examples.

<Method of Measuring Bleed-Out of Liquid Component>

(1) Bleed-Out Measurement Method

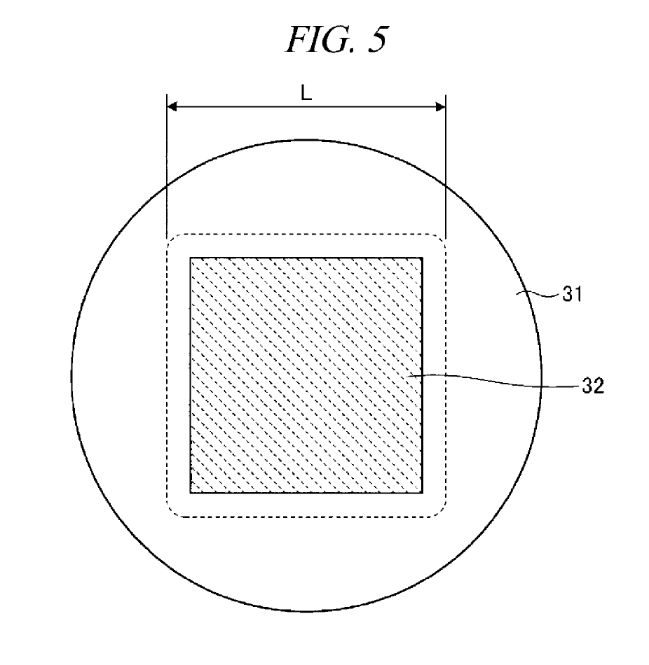

A filter paper having a diameter of 70 mm was prepared, and was heated and dried at 100° C. for 30 minutes or more, and then put into a desiccator at room temperature (25° C.) and left for 1 day. In this state, a weight (W0) of the filter paper was measured. A thermally conductive silicone sheet having a shape of 38 mm in length, 38 mm in width, and 3 mm in thickness was interposed between the two filter papers and kept under a load of 1 kg at 70° C. for 1 week. FIG. 5 is an explanatory diagram illustrating a state where a thermally conductive silicone sheet 32 was placed at a substantially central portion of a filter paper 31. Then, the silicone sheet was immediately separated, and then, a weight (W1) of the filter paper was measured at a condition where the filter paper was put into a desiccator at room temperature (25° C.) and left as it was for 1 day. A bleed-out amount (W1-W0) was calculated.

(2) Measurement Method of Adsorption Width into Filter Paper

An adsorption width into the filter paper used in measuring the bleed-out amount was measured. As depicted in FIG. 5, an oil bleeding width (L) was regarded as an adsorption width.

<Thermal Conductivity Measurement Method>

A thermal conductivity was measured by a hot disc method by using thermophysical property measuring apparatus TPA-501 (product name) manufactured by Kyoto Electronics Manufacturing Co., Ltd. A sample to be measured was prepared as follows.

A sheet having a thickness of 3 mm and prepared by a sheet forming method as described in each of the experimental examples and comparative examples was cut into 50 mm in length and 50 mm in width, and the three sheets were stacked to be become a single block. The two blocks were prepared, and a sensor including a heating source and a temperature detection unit was interposed between the two blocks to measure a thermal conductivity.

The blocks and the sensor were covered in order not to be exposed to an air and left for 15 minutes. Then, a thermal conductivity was measured.

### Experimental Example 1

### Component (A)

70 parts by weight of dimethylpolysiloxane having a viscosity of 0.4 Pa·s at 23° C. and blocked by a dimethylvinylsiloxy group at both ends of a molecular chain, and 30 parts by weight of siloxane expressed by [(CH₃)₃SiO_{1/2}]_{2.8}[SiO_{4/2}]

### Component (B)

1.06 parts by weight of polyorganohydrogen siloxane expressed by C₆H₅Si[OSi(CH₃)₂H]₃

### Component (C)

5 ppm of a vinylsiloxane complex compound of chloroplatinic acid as a platinum element, and 0.04 parts by weight of 1-ethynyl-1-cyclohexanol

### Component (D)

300 parts by weight of silica particles having an average particle diameter of 30 μm with respect to total 100 parts by weight of the component (A) and the component (B)

The above-described components were put into a kneading machine and uniformly mixed to obtain a composition. This composition was formed into an elongated sheet of 200 mm in width and 3.0 m in length and heated and hardened (cross-linked) at 100° C. for 10 minutes. The sheet obtained as described above has properties as shown in Table 1.

### Comparative Example 1

The comparative example 1 was conducted in the same manner as the experimental example 1 except that dimethylpolysiloxane having a viscosity of 0.4 Pa·s at 23° C. and blocked by a dimethylvinylsiloxy group at both ends of a molecular chain was used in an amount of 100 parts by weight and silioxane expressed by [(CH₃)₃SiO_{1/2}]_{2.8}[SiO_{4/2}] was not used instead of the component (A) in the experimental example 1. The sheet obtained as such had properties as shown in Table 1.

### Experimental Example 2

The experiment example 2 was conducted in the same manner as the experimental example 1 except that the component (B) (cross-linking agent) and the component (D) (thermally conductive particles) of the experimental example 1 were changed as follows.

Component B (Cross-linking agent): 0.4 parts by weight of polyorganohydrogen siloxane expressed by C₆H₅Si[OSi(CH₃)₂H]₃

Component D (Thermally conductive particles):

(1) 200 parts by weight of alumina having an average particle diameter of 3 μm with respect to total 100 parts by weight of the component (A) and the component (B)

(2) 100 parts by weight of alumina having an average particle diameter of 0.3 μm with respect to total 100 parts by weight of the component (A) and the component (B)

(3) 200 parts by weight of aluminum nitride having an average particle diameter of 80 μm with respect to total 100 parts by weight of the component (A) and the component (B)

Note: Among the above particles, the elementary particles having an average particle diameter of 3 μm or less were surface-treated with silane and then added. Hexyltriethoxysilane was used as silane and treated at 100° C. for 2 hours.

TABLE 1

| | Thermal conductivity | Hardness | Liquid bleed-out |
|---|---|---|---|
| | (W/m · K) | (ASKER C) | (mg) |
| Experimental | 1 | 15 | 25.5 |
| example 1 | | | |
| Experimental | 2 | 30 | 11.9 |
| example 2 | | | |
| Comparative | 2 | 20 | 40.6 |
| Example 1 | | | |

As can be clearly seen from Table 1, the sheet of the experimental example 1 was a thermally conductive silicone sheet having a small bleed-out amount of a liquid component such as silicone oil or oligomer. The sheet of the experimental example 2 had a higher thermal conductivity.

### Experimental Example 3

With the plasma processing apparatus as depicted in FIG. 2 and FIG. 3, heat controllability of the focus ring by the thermally conductive silicone sheet 27 was measured in the case of using the thermally conductive silicone sheet 27 of the above-described experimental example 2 (Experimental example 3) and in the case of using the thermally conductive silicone sheet 27 of the above-described comparative example 1 having a large bleed-out (Comparative Example 2).

To be more specific, in the experimental example 3, the thermally conductive silicone sheet 27 (film thickness of 0.5 mm) of the above-described experimental example 2 was provided between the upper member 3a and the lower member 3b of the focus ring 3, and the thermally conductive silicone sheet 27 (film thickness of 0.5 mm) of the comparative example 1 was provided between the lower member 3b and the electrostatic chuck 12, and then, a plasma process was performed. Further, in the comparative example 2, the thermally conductive silicone sheet 27 (film thickness of 0.5 mm) of the above-described comparative example 1 was provided between the upper member 3a and the lower member 3b of the focus ring 3, and the thermally conductive silicone sheet 27 (film thickness of 0.5 mm) of the comparative example 1 was also provided between the lower member 3b and the electrostatic chuck 12, and then, the same plasma process was performed, and the experimental example 3 and the comparative example 2 were compared to each other.

In performing the plasma process, plasma was generated by applying a high frequency power under the conditions of a processing chamber pressure of 2.6 Pa, a gas flow rate: C₄F₆/C₄F₈/O₂/Ar=40/40/50/400 sccm, and a mounting table temperature of 20° C. and plasma etching was performed for 60 seconds. These conditions were the plasma process conditions where a SiO₂ film was etched with a polysilicon (PolySi) film or a photoresist film (PR) as an etching mask. A polysilicon (PolySi) film and a photoresist (PR) film formed as etching mask materials on a target substrate were respectively prepared, and the plasma process was performed. With respect to the experimental example 3 and the comparative example 2, etching rates PolySi E/R (nm/min) and PR E/R (nm/min) of the respective films were measured. Herein, since the polysilicon film and the photoresist film are used as the etching masks, it is desirable that the etching rate is low.

TABLE 2

| | PolySi E/R (nm/min) | PR E/R (nm/min) |
|---|---|---|
| Experimental | 12.6 | 20 |
| example 3 | | |
| Comparative | 13.9 | 23.6 |
| Example 2 | | |

As shown in Table 2, it can be seen that the experimental example 3 can control an etching rate to be low as compared with the comparative example 2 in both of PolySi E/R (nm/min) and PR E/R (nm/min). From this result, it can be seen that in the plasma processing apparatus of the experimental example 3, an etching rate of the mask material is controlled to be low. An etching rate is highly relevant to a temperature of a focus ring. To be specific, as a temperature of the focus ring increases, more radicals contributing the etching on the focus ring are consumed, so that the etching rate decreases. From this result, it can be seen that a temperature of the focus ring in the experimental example 3 can be set to be high and a selectivity of the etching mask is improved as compared with the comparative example 2.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

We claim:

1. A thermally conductive silicone sheet for a plasma processing apparatus, having 100 parts by weight to 2000 parts by weight of thermally conductive particles with respect to 100 parts by weight of polyorganosiloxane,
wherein the sheet has a thermal conductivity of 0.2 W/m·K to 5 W/m·K and a hardness of 5 to 60 (ASKER C), and
when the sheet has a shape of 38 mm in length, 38 mm in width, and 3 mm in thickness and is interposed between filter papers each having a diameter of 70 mm and kept under a load of 1 kg at 70° C. for 1 week, a bleed-out amount of a liquid component is 30 mg or less.

2. The thermally conductive silicone sheet of claim 1,
wherein the thermally conductive particles include at least two inorganic particles having average particle diameters different from each other, and
the inorganic particles having a relatively smaller average particle diameter are surface-treated with a silane compound expressed by R(CH₃)ₐSi(OR′)₃₋ₐ (R represents a substituted or unsubstituted organic group having 6 to 20 carbon atoms, R′ represents an alkyl group having 1 to 4 carbon atoms, and a is 0 or 1), or a partial hydrolysate thereof.

3. The thermally conductive silicone sheet of claim 1,
wherein the thermally conductive particles includes at least one selected from a group consisting of alumina, zinc oxide, magnesium oxide, aluminum nitride, boron nitride, aluminum hydroxide, and silica.

4. The thermally conductive silicone sheet of claim 3,
wherein the alumina is α-alumina having a purity of 99.5 weight % or more.

5. The thermally conductive silicone sheet of claim 1,
wherein inorganic pigment particles are further added into the thermally conductive silicone sheet.

6. A manufacturing method of the thermally conductive silicone sheet for the plasma processing apparatus of claim 1, the manufacturing method comprising:
forming the sheet by sheet-forming and cross-linking a compound having compositions of:
base polymer component (A): A straight chain organopolysiloxane having, on average, two or more alkenyl groups bonded with a silicon atom at both ends of a molecular chain in one molecule and a branched silicone resin without having an aliphatic unsaturated bond but including a R¹SiO_{3/2} unit and/or a SiO_{4/2} unit are included. Here, R¹ represents an organic group which is an unsubstituted monovalent hydrocarbon group or substituted monovalent hydrocarbon group in which at least a part of hydrogen atoms bonded to a carbon atom are substituted with a halogen atom or a cyano group, without having an aliphatic unsaturated bond;
cross-linking component (B): A polyorganohydrogen siloxane expressed by R²Si(OSiR³₂H)₃ has 0.3 to 1.5 SiH groups with respect to one alkenyl group of the component (A). Here, R² represents an alkyl group or a phenyl group having 1 to 4 carbon atoms, and R³ represents an alkyl group having 1 to 4 carbon atoms;
platinum-based metal catalyst (C): 0.01 ppm to 1000 ppm in a weight unit with respect to the component (A); and
thermally conductive particle (D): 100 to 2000 parts by weight with respect to total 100 parts by weight of the component (A) and the component (B).

7. A plasma processing apparatus comprising: a decompressed accommodation chamber in which a target substrate is accommodated; a mounting table which is provided within the accommodation chamber to mount thereon the target substrate and has a cooling device; and an annular focus ring which is mounted on the mounting table to surround a periphery of the target substrate,
wherein a thermally conductive silicone sheet is provided between the mounting table and the focus ring, and
the thermally conductive silicone sheet has 100 parts by weight to 2000 parts by weight of thermally conductive particles with respect to 100 parts by weight of polyorganosiloxane, and the sheet has a thermal conductivity of 0.2 W/m·K to 5 W/m·K and a hardness of 5 to 60 (ASKER C), and when the sheet has a shape of 38 mm in length, 38 mm in width, and 3 mm in thickness, and is interposed between filter papers each having a diameter of 70 mm and kept under a load of 1 kg at 70° C. for 1 week, a bleed-out amount of a liquid component is 30 mg or less.

8. The plasma processing apparatus of claim 7, further comprising:
a pressing unit configured to press the focus ring against the mounting table.

9. The plasma processing apparatus of claim 8,
wherein the focus ring includes a ring-shaped lower member in contact with the mounting table and a ring-shaped upper member mounted on the lower member via the thermally conductive silicone sheet, and the pressing unit fastens the lower member to the mounting table by screw fixing.

10. The plasma processing apparatus of claim 9,
wherein the lower member is made of a dielectric material or a conductive material.
